(19) United States
(12) Patent Application Publication
(10) Pub. No.: US 2018/0301666 A1
(43) Pub. Date: Oct. 18, 2018

(54) METHOD OF MAKING AN ELECTRONIC DEVICE

(71) Applicant: Cambridge Display Technology Limited, Cambridgeshire (GB)

(72) Inventor: Colin Baker, Cambridge (GB)

(73) Assignee: Cambridge Display Technology Limited, Cambridgeshire (GB)

(21) Appl. No.: 15/737,901

(22) PCT Filed: Jun. 10, 2016
(86) PCT No.: PCT/GB2016/051732

§ 371 Date: Dec. 19, 2017

(51) Int. Cl. H01L 51/56; H01L 51/00

(52) U.S. Cl. CPC H01L 51/56; H01L 51/0007; H01L 51/5209; H01L 51/0028; H01L 51/0023

(57) ABSTRACT

A method of fabricating an organic light emitting device comprises patterning a first electrode layer to form a grid comprising a mesh of electrically conductive metal tracks, depositing a layer of hole injection material from a solution comprising less than 10% solids by weight in a solvent, the thickness of the wet layer of solution before the solvent is evaporated to dry the film being greater than the track spacing, evaporating the solvent to provide a dry film having an average thickness in the spacing between the tracks which is less than 10% of the wet thickness of the wet layer of solution and an average thickness in the spacing between the tracks which is greater than 25% of the track thickness to provide a more planar top surface than the surface of the metal tracks before the layer of hole injection material was deposited, depositing one or more further layers from solution to provide a light emitting layer and one or more optional charge transporting layers, and depositing a second electrode layer. The grid can comprise sets of tracks having different widths and spacings.

### FIELD OF THE INVENTION

This invention generally relates to a method of making an electronic device, in particular lighting devices, in which an electrode layer of the electronic device comprises first and second electrically conductive grids, and to such an electronic device.

### BACKGROUND TO THE INVENTION

Recently, metal grids have been exploited in electronic devices to improve device performance. This is particularly the case for large area lighting tiles, where a more uniform light emission may be achieved over the tile as the voltage drop over the anode (or cathode) is distributed more evenly.

For example, in GB 2482110 A, the metal electrode layer is provided as a grid structure. The metal grid may be obtained using standard deposition and patterning/lithography techniques known to those skilled in the art. A separate thin film is used to provide conduction between tracks of the grid.

In order to understand embodiments of the present invention, the following describes the general structure of a light-emitting device currently employed in the art. Therefore, FIG. 1 shows a schematic, cross-sectional side view of a part of a light-emitting device (100) according to the prior art.

In this example, an indium tin oxide (ITO) layer (104) is deposited on top of a glass substrate (102). ITO is commonly used as an anode material, in particular in organic light-emitting devices, as it has a high work function resulting in a high hole-injection efficiency into the highest occupied molecular orbital (HOMO) of an organic layer. Furthermore, ITO exhibits a low absorption in the visible spectrum, making it suitable for an electrode layer in a light-emitting device.

In a standard light-emitting device, an anode comprises a metal electrode layer (106) which is prepared and patterned on top of the ITO layer (104). Typically, a hole-injection layer (108) is arranged on top of the ITO layer (104), covering the electrodes of the metal electrode layer (106). An emission layer (110) is then deposited on top of the hole-injection layer (108), followed by a cathode (not shown in FIG. 1).

As shown in the prior art, exploiting a metal grid (106) results in a more uniform light emission, in particular for large area tiles, as the voltage drop is more evenly distributed over the anode. Therefore, charges are more evenly injected from the metal anode via the hole-injection layer (108) into the light-emitting layer (110), resulting in a more uniform luminance profile in a lateral direction of the large area device.

FIG. 2 shows a schematic, cross-sectional side view of such a light-emitting device (200) in which a metal grid (106) is provided on top of the ITO layer (104).

An optional electrically insulating bank layer (202) may be prepared on top of the metal tracks (106) of the anode before depositing an ink comprising the hole-injection layer (108) onto the ITO layer (104) to isolate specific tracks.

FIG. 2 shows a complete lighting device (200) structure in which a hole-transport layer (204) is prepared on top of the hole-injection layer (108), followed by a light-emitting layer (here a light-emitting polymer 206), and a cathode (208).

Optionally, an external scattering film (210) may be prepared on a side of the substrate (102) which is opposite to the side of the substrate on which the active device parts are arranged.

FIG. 3a shows a top-view of the luminance of a lighting tile (300), whereby the anode is not provided with a metal grid. As can be seen, a higher luminance is observed at the edges of the lighting tile (300) where it is connected to electrical busbars (302).

FIG. 3b shows a photographic image of a lighting tile (304), wherein the anode comprises a metal grid (not shown). It can be seen that a more uniform light emission is obtained due to a more uniform voltage drop in a lateral direction over the anode.

Even though ITO is a suitable material, in particular for lighting devices due to its transparency in the visible spectrum and its high work function, it is relatively expensive mainly due to a limited supply of indium. The fabrication costs of electronic devices using ITO are further increased as costly vacuum deposition techniques are required for processing ITO.

Furthermore, as shown in FIG. 2, the prior art generally exploits a large number of different layers in a light-emitting device. The device preparation is therefore relatively complex and costly.

Thickness variations in the light emitting layer can result in lower efficiency, reduced lifetime, and non-uniformity in illumination. For these reasons a planarising layer is generally provided between the metal tracks and the hole injection layer to improve step coverage and minimize thickness variations in subsequent layers deposited from solution.

There is therefore a need for further improvements of such electronic devices to mitigate such problems.

### SUMMARY OF THE INVENTION

According to a first aspect of the invention, there is provided a method of fabricating an organic light emitting device, the device comprising: a substrate having a major surface; a first electrode layer; a second electrode layer; and an organic light emitting layer positioned between and in electrical contact with the first and second electrode layers, the method comprising:
a. patterning the first electrode layer to form a grid comprising a mesh of electrically conductive metal tracks having a track width w and a track spacing s in a plane parallel to the major surface of the substrate, and a track thickness t in a plane perpendicular to the major surface of the substrate, the method comprising
b. depositing a layer of hole injection material from a solution comprising less than 10% solids by weight in a solvent, the thickness of the wet layer of solution before the solvent is evaporated to dry the film being greater than the track spacing s;
c. evaporating the solvent to provide a dry film having an average thickness in the spacing between the tracks which is less than 10% of the wet thickness of the wet layer of solution and an average thickness in the spacing between the tracks which is greater than 25% of the track thickness to provide a more planar top surface than the surface of the metal tracks before the layer of hole injection material was deposited;
d. depositing one or more further layers from solution to provide a light emitting layer and one or more optional charge transporting layers; and
e. depositing a second electrode layer.

By having a first electrode grid with a mesh spacing much less than the wet thickness of a subsequently deposited hole injection layer, very good planarization is achieved without the need for an additional planarization step. Thus an additional planarization layer is unnecessary and the device is simpler and cheaper to make.

According to a second aspect of the invention, there is provided an organic light emitting device as specified in claim 11.

In a preferred embodiment, the organic light emitting device comprises: a substrate bearing a layered structure extending laterally over said substrate, wherein said layered structure comprises: a first electrode layer; a second electrode layer; and a light emitting layer between said first and second electrode layers; wherein said first electrode layer comprises: a first electrically conductive grid comprising a first plurality of electrically conductive tracks; and a second electrically conductive grid comprising a second plurality of electrically conductive tracks; wherein a first width of each of said first plurality of electrically conductive tracks is smaller than a second width of each of said second plurality of electrically conductive tracks; and wherein said first electrically conductive grid is disposed between tracks of said second plurality of electrically conductive tracks.

The inventors have identified that disposing a first plurality of electrically conductive tracks between tracks of a second plurality of electrically conductive tracks, whereby the width of the first plurality of tracks is smaller than the width of the second plurality of tracks, has several significant advantages over devices of the prior art which use a single grid as an electrode.

By disposing a first electrically conductive grid between tracks of a second plurality of electrically conductive tracks of a second electrically conductive grid, an electronic device of the general type described herein may be prepared without the need of a (transparent) planarization layer.

Such a (transparent) planarization layer has become the standard in devices of the prior art in which a single grid is exploited, as an electrode layer consisting of a single grid without a planarization layer results in a non-uniform charge carrier injection into the active layer in a lateral direction of the electronic device.

By contrast, by providing a first electrically conductive grid disposed between tracks of a second plurality of electrically conductive tracks as in the present invention, the uniformity of the voltage drop over the first electrode layer may be significantly increased. This may enhance a more uniform charge carrier injection into the active layer in a lateral direction of the electronic device. Therefore, particularly in light-emitting devices, the uniformity of the luminance over the lighting device may thereby be improved significantly.

As will be further described below, a planarized grid may be advantageous particularly for solution-processed devices, as the solution-deposited layer on top of the first electrode layer generally adopts the surface profile of the first electrode layer.

Generally, depositing a charge-injection layer onto tracks of an electrode may result in a stepped topography on the surface of the charge-injection layer. These steps may have a height between a few nm to a few tens of nm, or even more. Preferably, these steps are to be avoided as they may give rise to an enhanced charge carrier injection into the active layer in regions of the operational area of the electronic device where the steps cause thinning of subsequent layers. This is because in a vertical device, steps may result in a reduced, effective thickness of the active layer compared to areas where no steps are present. A key parameter of layers prepared in a vertical device, in particular that of the charge-injection layer (e.g. an anode comprising a conductive grid and a hole-injection layer), is the sidewall angle. A sidewall angle of the charge-injection layer may be defined as an angle formed between a first line which is parallel to the substrate and a second line defined by a sidewall of a step, which may, in some cases, have a trapezoidal shape. Preferably, this sidewall angle is as small as possible so that the effective thickness of the subsequently deposited active layer is uniform over the entire lateral area of the device. A sidewall angle of zero degrees means that no steps are present.

Therefore, in a preferred embodiment of the electronic device, a sidewall angle of the charge-injection layer on the first electrode layer is less than 5 degrees, preferably less than 2 degrees, or even more preferably less than 1 degree. This is particularly preferable in light-emitting devices, because the smaller the sidewall angle of the charge-injection layer, the more uniform the light emission over the lateral operational area of the lighting device.

In the prior art, a sidewall angle of the charge-injection layer of, or close to 1 degree may only be achieved using an additional planarization layer disposed between metal grids. As outlined above, however, the present invention allows for eliminating the need for an additional planarization layer by using a thick wet thickness of hole or electron injecting material deposited from solution over a metal grid with very fine dimensions to provide a substantially planar upper surface for subsequent deposition of other active layers such as the light emitting layer.

As will be further described below, by reducing the dimensions of the width and average spacing between tracks of the electrically conductive tracks, the desired planarization may be achieved by using, for example, a hole-injection layer as part of the anode (or electron-injection layer as part of the cathode) without the need for an additional planarization layer. This may be most apparent when the average spacing of the electrically conductive tracks is comparable to, or (significantly) less than the wet thickness of the hole-injection (or electron-injection) layer during deposition from solution.

It will be appreciated that in particular in light-emitting devices, it may be necessary to reduce the width of electrically conductive tracks as the average spacing between tracks of the first and second plurality of tracks, respectively, is reduced in order to maintain a sufficient optical transmission of the electrode layer. Particularly suitable methods will be further described below, and may comprise nanoimprint lithography and phase shift lithography using phase-shift masks.

A further advantage of reducing the average spacing between tracks and their width is that the device luminance may be enhanced even further, as will be described below, since the grid may be used as an optical diffraction grating when dimensions of average spacing and width of tracks are comparable to the wavelength of the light emitted by the device.

A further advantage of the present invention over the prior art is that the necessity of an unpatterned ITO layer (or other, preferably transparent conducting layer) is eliminated. Therefore, production costs and the complexity of fabricating such electronic devices may be reduced even further compared to the prior art as the ITO layer may be omitted.

The first and second electrically conductive grids generally cover an operational area of the electronic device. The first and second electrically conductive grids overlap, so that tracks of the first plurality of electrically conductive tracks provide for electrical connection between tracks of the second plurality of electrically conductive tracks. An electrical busbar may be provided at one or more locations around the operational area of the device. The busbar may be connected to one or both of the first electrically conductive grid and the second electrically conductive grid. The main purpose of the busbar is therefore to conduct a generally substantial electrical current to be provided to the first and/or second electrically conductive grids, whereas the busbar does not function as a structural member of the electronic device in the operational, active area.

The first and second plurality of electrically conductive tracks may comprise a metal, such as, but not limited to Au, Ag, Ni, Al, Cu, Co, or an alloy, such as, but not limited to AgBi or AgCo. Alternatively, the first and second plurality of electrically conductive tracks may comprise an organic material, for example a conducting polymer. The first and second plurality of electrically conductive tracks may alternatively comprise nanowires comprising, for example Ag nanowires. When exploiting nanowires, it must be ensured that the nanowires overlap in order to guarantee an electrical connection between tracks of the grids.

The skilled person will appreciate that the material or material composition used for the first and second plurality of electrically conductive tracks may be chosen dependent on the specific properties required for the anode and/or cathode of the electronic device. For example, the work function (or, as the case may be, the highest or lowest occupied molecular orbital of the organic conducting material) may be chosen to yield a high injection efficiency of charge carriers (holes or electrons) into the active layer (or another neighbouring layer).

Generally, the second electrically conductive grid provides for large area conduction and the first electrically conductive grid is used for lateral conduction between the second plurality of electrically conductive tracks of the second electrically conductive grid.

Therefore, in preferred embodiments of the electronic device, the first width of each of the first plurality of electrically conductive tracks is less than 2 μm, preferably less than 1 μm, more preferably less than 0.5 μm, more preferably less than 0.2 μm, more preferably less than 0.1 μm, or even more preferably less than 0.05 μm. The width of electrically conductive tracks refers to a lateral width of the tracks in a plane parallel to a major surface of the substrate throughout the description.

It will be understood that an average spacing between tracks of the first plurality of electrically conductive tracks and the average spacing between tracks of the second plurality of electrically conductive tracks may be varied depending on the specific requirements of the first electrode layer. Particularly, a specific sheet resistance of the first grid, a specific sheet resistance of the second grid, or, generally, a specific sheet resistance of the first electrode layer may be desirable. The sheet resistance may be varied by varying one or both of the width of the tracks of first and second electrically conductive grids, respectively, and an average spacing between tracks of the first electrically conductive grid and/or between tracks of the second electrically conductive grid.

In a preferred embodiment of the electronic device, a first average spacing between tracks of the first plurality of electrically conductive tracks is smaller than a second average spacing between tracks of the second plurality of electrically conductive tracks. In a further preferred embodiment, the first average spacing between tracks of the first plurality of electrically conductive tracks is less than 20 μm, preferably less than 10 μm, more preferably less than 5 μm, more preferably less than 2 μm, more preferably less than 1 μm, or even more preferably less than 0.5 μm. Generally, reducing the width of the tracks of both the first electrically conductive grid and the second electrically conductive grid may advantageously improve an aperture ratio of the first electrode layer. The aperture ratio of the electrode layer is defined via its transmissivity, that is the ratio between the light transmissive area of the surface and the total lateral area including the opaque tracks. In a preferred embodiment of the electronic device, the first electrode layer comprises an aperture ratio of more than 80%, preferably more than 85%, more preferably more than 90%, or even more preferably more than 95%.

In order to improve the charge carrier injection efficiency into the active layer, an additional charge-injection layer may be prepared between the active layer and the first and second electrically conductive grids, respectively. Therefore, in a preferred embodiment of the electronic device, the first electrode layer may further comprise a charge-injection layer. Preferably, the charge-injection layer covers the first and second electrically conductive grids, respectively, to prevent charges from being injected directly from the first and second electrically conductive grids into the active layer. In such a configuration, the combination of electrically conductive grids and charge-injection layer may be considered as an anode (or cathode) of the electronic device.

A charge-injection layer as described above may comprise a hole-injection layer or an electron-injection layer, depending on whether the first electrode layer is used as an anode or cathode, respectively. In some embodiments, the hole-injection layer may comprise a p-doped hole-injection layer. Similarly, the electron-injection layer may in some embodiments comprise an n-doped electron-injection layer. The skilled person will appreciate that a suitable hole-injection layer or electron-injection layer may depend on, for example, the work function of the first and second electrically conductive grids, as well as a work function or highest/lowest occupied molecular orbital of the active layer. Suitable materials for the charge-injection layer will be known to those skilled in the art.

Generally, it is desirable for the first electrode layer (and similarly the second electrode layer) to exhibit a roughness which is as low as possible. A rough electrode layer on a surface which faces towards the active layer may result in a non-uniform charge carrier injection in a lateral direction, i.e. a lateral operational area of the device. This may, for example in light-emitting devices, result in an undesirable, non-uniform luminance.

In a preferred embodiment of the electronic device, the charge-injection layer comprises a first organic semiconductor or a first organic semiconductor composition. The first organic semiconductor or first organic semiconductor composition may be solution-processable. Solutions of hole-injection material or electron injection material are well known and include materials commercially available from Nissan, Plextronics/Solvay, Agfa, and Hereaus and Novaled. Examples of well-known hole injection materials include PEDOT:PSS, polyaniline, or semiconducting polymers such as PVK or poly arylamines.

As outlined above, using a combination of charge-injection layer and electrically conductive grids, an additional planarization step and/or and additional infill planarization layer may be omitted. The combination of charge-injection layer and electrically conductive grids may, when used in a lighting device, yield a more uniform emission and/or a higher efficiency of the device compared to the prior art.

The planarization of the first electrode layer may be improved even further by using a charge-injection layer with a high viscosity. Alternatively or additionally, when the charge-injection layer is solution-processed, a specific compound may be added to the solvent of the charge-injection layer to increase a boiling point of the solvent mixture. An increased boiling point may generally result in a better planarization of the charge-injection layer on top of the electrically conductive grids, and hence an improved planarization of the first electrode layer. The skilled person will be familiar with suitable solvents for a specific charge-injection layer to increase the planarization of the first electrode layer prior to depositing the active layer and/or other layers.

In order to transport current over a large lateral area of the first electrode layer, it is preferable to reduce a sheet resistance of the first electrode layer below a threshold sheet resistance. Therefore, in a preferred embodiment of the electronic device, the first electrode layer comprises a sheet resistance of less than 10 Ohms/sq, preferably less than 5 Ohms/sq, more preferably less than 2 Ohms/sq, or even more preferably less than 1 Ohm/sq.

Using a first electrically conductive grid disposed between tracks of a second plurality of electrically conductive tracks of a second grid is particularly advantageous over the prior art in this regard. Exploiting first and second grids as described herein may allow reducing the sheet resistance to a low value, e.g. below 2 Ohms/sq, without the need of a grid with comparatively large-thickness tracks. The thickness here refers to an extension in a direction perpendicular to a plane of the substrate. Therefore, production costs of the electronic device may be reduced further compared to the prior art.

Embodiments of the electronic device described herein may be used in a variety of applications. In a preferred embodiment, the electronic device is a lighting device. Such a lighting device may be, but is not limited to a light-emitting diode, in particular an organic light-emitting diode.

Generally, in embodiments in which the electronic device comprises organic materials so as to be flexible, it is preferable to avoid the use of ITO since ITO is relatively fragile/brittle compared to organic materials. Embodiments described herein allow for omitting a continuous conducting layer such as an unpatterned layer of ITO.

Where the electronic device is employed in a lighting device, it may be preferable to provide light-transmissive layers which do not absorb light generated by the active layer. Therefore, in a preferred embodiment of the electronic device, the substrate is light-transmissive.

The skilled person will appreciate that the substrate being light-transmissive means that the substrate does not absorb light at least at a wavelength or range/plurality of wavelengths at which light is generated by the active layer. The substrate not absorbing light is to be understood as to the substrate having a transmissivity above a threshold transmissivity.

In a further preferred embodiment of the electronic device, the substrate comprises an organic material or an organic material composition. This may allow for reducing fabrication costs of the electronic device even further. Examples of suitable substrate materials include glass, PEN, PET, COP, polycarbonate or other transparent plastic materials, flexible glass or composite materials.

If the electronic device is used as a lighting device, it is preferable to increase an aperture ratio of the first electrode layer through which light generated within the active layer passes. In a preferred embodiment of the electronic device, the first electrode layer comprises an aperture ratio of more than 80%, preferably more than 85%, more preferably more than 90%, or even more preferably more than 95%. In this regard, first electrode layer refers to the combined first and second electrically conductive grids, or, alternatively, to the combined first and second electrically conductive grids together with the charge-injection layer (e.g. hole-injection layer).

It will be understood that in order to improve the device performance, the aperture ratio may have to be adjusted to, on the one hand, to be sufficiently large to allow enough light to be able to penetrate the first electrode layer, and on the other hand to be sufficiently small to enable a large enough current to be distributed over the lateral area of the first electrode layer.

As outlined above, the active (light emitting) layer is arranged between the first and second electrode layers. The first electrode layer may be prepared on the substrate. Therefore, in a preferred embodiment of the electronic device, the first electrode layer is arranged on a first side of the active layer, wherein the first side faces towards the substrate. In this device structure, the first electrode layer is the bottom electrode layer comprising first and second electrically conductive grids.

Alternatively, the top electrode layer may comprise first and second electrically conductive grids as described herein. Therefore, in an alternative embodiment of the electronic device, the first electrode layer is arranged on a first side of the active layer, wherein the first side faces away from the substrate.

Additionally, the second electrode layer may also comprise electrically conductive grids generally as described herein. Therefore, in a another embodiment of the electronic device, the second electrode layer comprises a third electrically conductive grid comprising a third plurality of electrically conductive tracks; and a fourth electrically conductive grid comprising a fourth plurality of electrically conductive tracks; wherein a third width of each of said third plurality of electrically conductive tracks is smaller than a fourth width of each of said fourth plurality of electrically conductive tracks; and wherein said third electrically conductive grid is disposed between tracks of said fourth plurality of electrically conductive tracks.

Providing both first and second electrode layers with electrically conductive grids may be particularly preferable, for example in a light-emitting device which is required to emit light towards both sides from the active layer.

Generally, the second electrode layer may further comprise preferred features and properties as those described herein with regard to the first electrode layer.

In a related aspect of the invention, there is provided a lighting tile comprising the electronic device as described herein in any of the embodiments.

An advantage over the prior art is that the first and second electrically conductive grids may be prepared in a single fabrication sequence, i.e. simultaneously, using deposition, patterning (e.g. photo-patterning) and etching steps (not necessarily in this order, as will be appreciated by the skilled person). As an alternative the conductive tracks may be patterned using a lift-off technique.

Therefore, in a related aspect of the invention, there is provided a method of fabricating an electronic device, wherein said electronic device comprises a substrate bearing a layered structure extending laterally over said substrate, wherein said layered structure comprises a first electrode layer, a second electrode layer, and an active layer between said first and second electrode layers, the method comprising: preparing, in a single processing sequence, a first electrically conductive grid of said first electrode layer and a second electrically conductive grid of said first electrode layer, wherein said first electrically conductive grid comprises a first plurality of electrically conductive tracks, and said second electrically conductive grid comprises a second plurality of electrically conductive tracks; wherein a first width of each of said first plurality of electrically conductive tracks is smaller than a second width of each of said second plurality of electrically conductive tracks; and wherein said first electrically conductive grid is disposed between tracks of said second plurality of electrically conductive tracks.

In a preferred embodiment of the method, the single processing sequence comprises a nanolithography technique. This nanolithography technique may be, but is not limited to nanoimprint lithography or roll-type phase lithography (as described in Nanotechnology 23 (2012) 344008).

By using a single electrically conductive layer patterned with a nano-patterning step, the ITO layer and conventional grid may be replaced by two grids as described in embodiments herein. The cost and complexity of the fabrication process may therefore be reduced significantly. The single processing sequence for simultaneously preparing tracks of both the first and second grids may further improve compatibility with roll-to-roll fabrication processes.

### BRIEF DESCRIPTION OF THE DRAWINGS

These and other aspects of the invention will now be further described by way of example only, with reference to the accompanying Figures, wherein like numerals refer to like parts throughout, and in which:

FIG. 1 shows a schematic, cross-sectional side view of a part of a light-emitting device according to the prior art;

FIG. 2 shows a schematic, cross-sectional side view of a light-emitting device according to the prior art;

FIGS. 3a and 3b show luminance distribution and a photographic image of a lighting tile according to the prior art;

FIG. 4 shows a schematic, cross-sectional side view of a light-emitting device according to embodiments of the present invention;

FIGS. 5a and 5b show schematic top-views of lighting tiles according to the prior art and embodiments of the present invention, respectively;

FIG. 6 shows a schematic, cross-sectional side view of a part of a light-emitting device according to embodiments of the present invention; and

FIG. 7 shows a schematic top-view of first and second grids according to embodiments of the present invention.

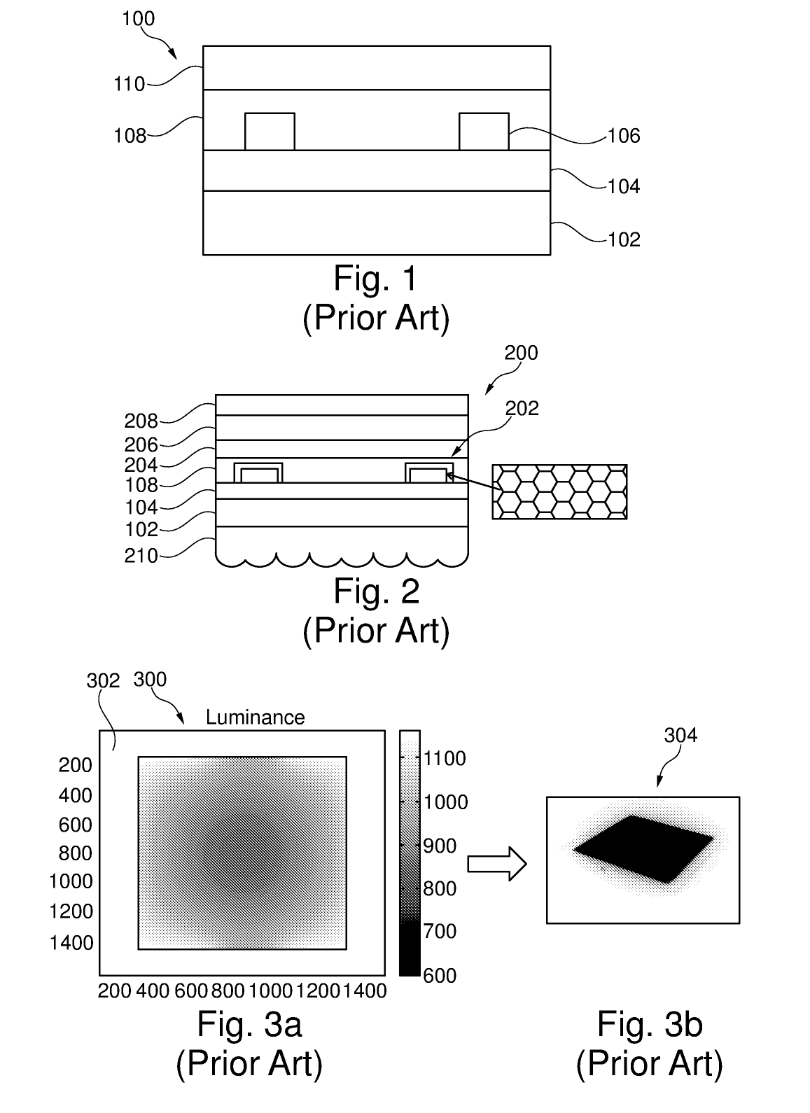

### DETAILED DESCRIPTION OF PREFERRED EMBODIMENTS

As outlined above, metal tracking has been exploited in the prior art in order to improve, e.g. the uniformity of light emission over large area tiles.

Typically, in the prior art, the metal grid and the lateral conductor are prepared in two separate deposition, photo-patterning and etching sequences. This results in high manufacturing costs.

Furthermore, as outlined above, an additional planarization layer, such as a transparent planarization layer in light-emitting devices, is generally necessary in devices of the prior art which use a single metal grid before deposition of the next active layer (such as hole-injection layer or light emitting layer.

Embodiments described herein allow for fabricating an electronic device without the need of an additional planarization layer (e.g. a transparent planarization layer in light-emitting devices).

Furthermore, a separate continuous, unpatterned lateral conductor, such as ITO, can be unecessary in embodiments described herein in which a nano-grid is employed, or in which a nanogrid is disposed between tracks of a macro-grid.

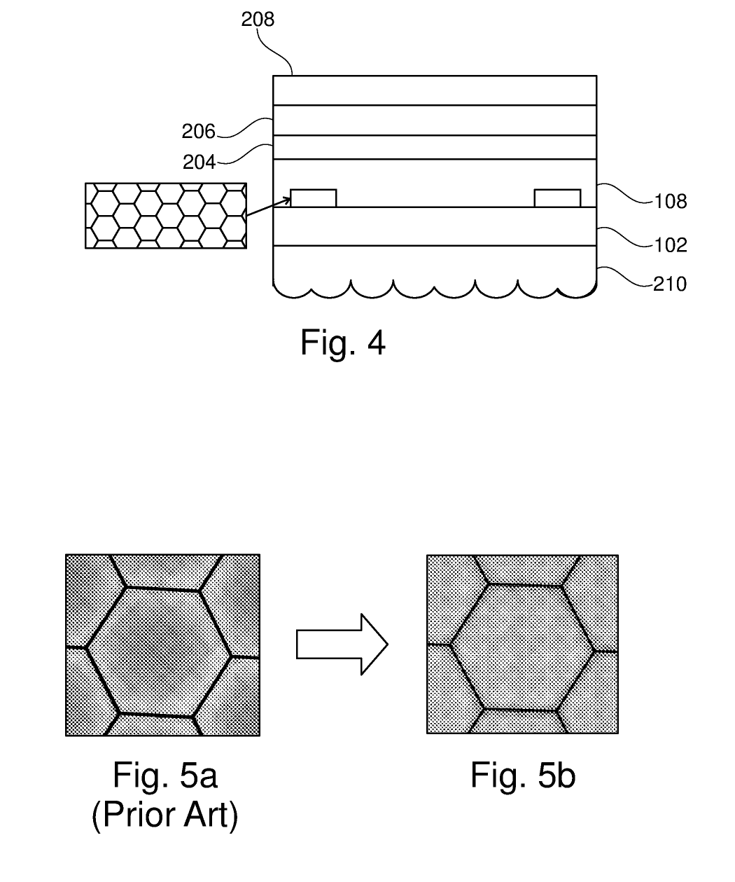

Referring now to FIG. 4, this shows a schematic, cross-sectional side view of a light-emitting device, in which the lateral conductor (such as an ITO layer) which may be prepared on top of the substrate has been omitted.

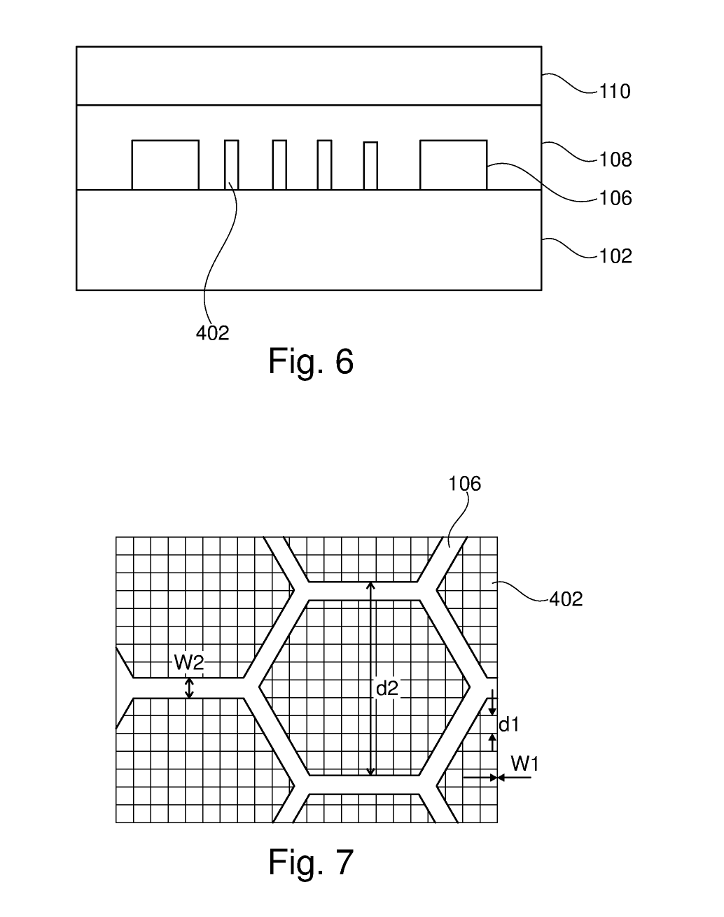

In this example, the anode comprises, in a single layer, a first electrically conductive grid (not shown here; see FIGS. 6 and 7 below) and a second electrically conductive grid (“metal tracking” shown in FIG. 4). The second electrically conductive grid is essentially a macro-grid for large area conduction. The first electrically conductive grid provides for lateral conduction between tracks of the macro-grid and is a nano-grid having fine dimensions.

An advantage over the prior art is that tracks of the first and second electrically conductive grids may be prepared in a single deposition, patterning and etching sequence. By using a single metal with a nano-patterning step to replace the ITO layer and conventional grid, the cost and complexity of the fabrication process may be reduced significantly. The single processing sequence for tracks of the nano-grid or both the macro-grid and the nano-grid may further improve compatibility with roll-to-roll fabrication processes. It should be pointed out that where a nano-grid and a macro-grid having different dimensions are used the thickness of the tracks in both grids in a direction perpendicular to the plane of the major surface of the substrate is the same.

The skilled person will be familiar with standard techniques for preparing patterned metal tracks on a substrate (such as glass). Suitable techniques include, but are not limited to nanolithography techniques, for example nanoimprint lithography or roll-type phase lithography (“Rolling Mask Lithography” developed by Rolith Inc.—see, e.g. Nanotechnology 23 (2012) 344008). Furthermore, as outlined above, nanoimprint lithography and phase change lithography allow for reducing the metal track width when the average spacing between tracks of the nano-grid and macro-grid, respectively, is reduced, while maintaining optical transmission in the case of a light-emitting device.

The inventors have identified that nanoimprint lithography and phase change lithography are particularly suitable for fabricating devices as described in embodiments herein. This is because the width of tracks and their average spacing may be reduced using these techniques such that an additional planarization layer is not required before depositing the hole-injection layer onto the layered structure, while obtaining the required planarization through having a very thick wet deposited layer prior to solvent evaporation—typically equal to or greater than the spacing between tracks.

For embodiments comprising both a nano-grid and a macro-grid, since the nano-grid and the macro-grid may be fabricated in a single processing sequence, tracks of the two grids have the same height. Furthermore, a small spacing (or average spacing) between the nano-grid tracks of generally less than 10 μm, more preferably less than 5 μm, more preferably less than 2 μm, more preferably less than 1 μm, or even more preferably less than 0.5 μm, may result in an increased planarization after the hole-injecting layer has been coated on top of the metal grids. Advantageously, no additional planarization step may be required after patterning the metal layer to form metal grids on the substrate in order to achieve a high planarization of the hole-injection layer on the metal grids.

Dependent on the spacing of tracks of the nano-grid and the wavelength of light emitted by the active layer, the nano-grid may be used as a diffraction grating. Therefore, as the dimensions of average spacing and width of the tracks of the nano-grid become comparable to the wavelength of the emitted light, using the nano-grid as a diffraction grating may advantageously enhance the device luminance. The nano-grid may therefore, in some embodiments, be used as a dispersive element.

It is understood that a sheet resistance of an electrode layer of less than 5 Ohms/sq may be desired for large area devices. This may allow for evenly supplying a current over a large area to obtain a uniform luminance. Using a nano-grid disposed between tracks of a macro-grid may provide for a small enough sheet resistance.

In order to reduce the sheet resistance of the electrode layer further, a high conductivity hole-injection layer may be provided on top of the metal grids (see FIG. 4). It will be appreciated that a standard hole-injection layer (std HIL in FIG. 4) may suffice to achieve a combined sheet resistance of the metal grids and hole-injection layer which is low enough (e.g. less than 5 Ohms/sq) for large area devices.

FIG. 5a shows a schematic top-view of a lighting tile according to the prior art, in which the anode merely comprises a macro-grid (dark tracks in FIG. 5a). In FIG. 5b, a nano-grid (not shown) is disposed between tracks of the macro-grid (dark tracks in FIG. 5b) according to embodiments described herein.

As can be seen, the uniformity of the luminance may be improved, in particular in areas distant from tracks of the macro-grid when a nano-grid is disposed between tracks of the macro-grid.

FIG. 6 shows a schematic, cross-sectional side view of a part of a light-emitting device according to embodiments described herein. The substrate (102) may, in this example, be a glass substrate or, alternatively, a plastic substrate.

Tracks of the metal electrode are shown for both the macro-grid (106) and the nano-grid (402).

The combined sheet resistance of macro-grid (106), nano-grid (402) and hole-injection layer (108) of less than 10 Ohms/sq, preferably less than 5 Ohms/sq, more preferably less than 2 Ohms/sq, or even more preferably less than 1 Ohm/sq, may be achieved using the shown device structure. In order to obtain a sheet resistance, in this example, of approximately 2 Ohms/sq, the bulk sheet resistance of the unpatterned grid material may be approximately 0.06 Ohms/sq. In this example, Ag metal tracks exhibit a thickness (in a direction perpendicular to the plane of the substrate) of approximately 250 nm to 300 nm.

The sheet resistance between tracks of the nano-grid (402) is, in this example, approximately 1 or 2 Ohms/sq.

As outlined above, the optional macro-grid (106) is a grid for large area conduction. The nano-grid (402) provides for lateral conduction between the macro-grid (106) when it is present.

FIG. 7 shows a schematic top-view of tracks of a macro-grid (106) and a nano-grid (402) according to embodiments of the electronic device described herein.

An aperture ratio of the electrode layer is defined via its transmissivity, that is the ratio between the transmissive portion of the layer and the overall lateral area covered by the layer. The aperture ratio of the macro-grid is preferably more than 85%, or more preferably more than 90%. In this example, the aperture ratio of the macro-grid (106) is approximately 95%.

As outlined above, in preferred embodiments, the aperture ratio of the electrode layer (i.e. the macro-grid (106), nano-grid (402), and optionally including the hole-injection layer (108)) is preferably more than 80%, preferably more than 85%, more preferably more than 90%, or even more preferably more than 95%.

In this example, the macro-grid (106) is shown as a hexagonal grid. However, it will be appreciated that the macro-grid may comprise any other shape, such as, but not limited to a square shape, a triangular shape or other shapes. In general, the grid defines apertures in the shape of a regular polygon.

Similarly, the nano-grid (402) may comprise any shape, such as, but not limited to a hexagonal shape, a square shape, a triangular shape or other shapes. In this example, the macro-grid (402) comprises a square shape. Again, in general the tracks of the nano-grid will define apertures in the shape of a regular polygon.

The thickness of the tracks of the macro-grid (106) and the nano-grid (402) may be varied, for example between 10 nm and 300 nm, depending on specific requirements of the device. In this example, the thickness of the Ag metal tracks is between approximately 250 nm and 300 nm.

The spacing (d1) between tracks of the nano-grid (402) is preferably as small as possible. However, the aperture ratio decreases the more the spacing (d1) is reduced. A compromise may have to be made, and in this example, the spacing (d1) of tracks of the nano-grid (402) is approximately 5 μm and the width (W1) of individual tracks of the nano-grid (402) is approximately 0.2 μm. Therefore, an aperture ratio of approximately 95% is achieved in this example.

The inventors have shown that for devices with d1≈5 μm and W1≈0.2 μm, no additional planarization layer is needed when a hole-injection layer (108) with a wet film thickness of approximately 20 μm is deposited on top of the nano-grid (402), while obtaining a side wall angle of the anode (i.e. combined metal grid and hole-injection layer (108)) of less than 10 degrees, less than 5 degrees, or even less than 1 degree.

Similar considerations apply for the tracks of the macro-grid (106). In this example, the spacing (d2) of tracks of the macro-grid (106) is approximately 1.23 mm and the width (W2) of individual tracks of the macro-grid (106) is approximately 30 μm.

No doubt many other effective alternatives will occur to the skilled person. It will be understood that the invention is not limited to the described embodiments and encompasses modifications apparent to those skilled in the art lying within the spirit and scope of the claims appended hereto.

1. A method of fabricating an organic light emitting device, the device comprising: a substrate having a major surface; a first electrode layer; a second electrode layer; and an organic light emitting layer positioned between and in electrical contact with the first and second electrode layers, wherein the method comprises:
a. patterning the first electrode layer to form a grid comprising a mesh of electrically conductive metal tracks having a track width w and a track spacing s in a plane parallel to the major surface of the substrate, and a track thickness t in a plane perpendicular to the major surface of the substrate;
b. depositing a layer of hole injection material from a solution comprising less than 10% solids by weight in a solvent, the thickness of the wet layer of solution before the solvent is evaporated to dry the film being greater than the track spacing s;
c. evaporating the solvent to provide a dry film having an average thickness in the spacing between the tracks which is less than 10% of the wet thickness of the wet layer of solution and an average thickness in the spacing between the tracks which is greater than 25% of the track thickness to provide a more planar top surface than the surface of the metal tracks before the layer of hole injection material was deposited;
d. depositing one or more further layers from solution to provide a light emitting layer and one or more optional charge transporting layers; and,
e. depositing a second electrode layer.

2. The method as claimed in claim 1, wherein the solution deposited in step b. comprises less than 3% solids by weight and the dry film in step c. has an average thickness in the spacing between the tracks which is less than 3% of the wet thickness of the wet layer.

3. The method as claimed in claim 1, wherein the first electrode layer is patterned to provide a grid comprising a first grid having a first plurality of electrically conductive tracks; and a second grid having a second plurality of electrically conductive tracks;
wherein the width (w1) of each of said first plurality of electrically conductive tracks is smaller than a width (w2) of each of said second plurality of electrically conductive tracks; and
wherein the tracks comprising said first grid are disposed between the tracks comprising said second grid.

4. The method as claimed in claim 3, wherein said first width is less than 1 μm, less than 0.5 μm, less than 0.2 μm, less than 0.1 μm, or less than 0.05 μm.

5. The method as claimed in claim 3, wherein the average spacing between tracks of said first plurality of electrically conductive tracks is smaller than the average spacing between tracks of said second plurality of electrically conductive tracks.

6. The method as claimed in claim 5, wherein said first average spacing is less than 5 μm, less than 2 μm, less than 1 μm, or less than 0.5 μm.

7. The method as claimed in claim 3, wherein the patterning of the first electrode layer to provide said first grid and said second grid of electrically conductive tracks is performed in a single patterning process.

8. The method as claimed in claim 7, wherein the single patterning process comprises a nanolithography technique.

9. The method as claimed in claim 8, wherein said nanolithography technique comprises nanoimprint lithography or roll-type phase lithography.

10. A lighting tile including an organic light emitting device prepared using a method as claimed in claim 1.

11. An organic light emitting device comprising: a substrate bearing a layered structure extending laterally over said substrate, wherein said layered structure comprises: a first electrode layer; a second electrode layer; and a light emitting layer between said first and second electrode layers; wherein said first electrode layer comprises: a first electrically conductive grid comprising a first plurality of electrically conductive tracks; and a second electrically conductive grid comprising a second plurality of electrically conductive tracks; wherein a first width of each of said first plurality of electrically conductive tracks is smaller than a second width of each of said second plurality of electrically conductive tracks; and wherein said first electrically conductive grid is disposed between tracks of said second plurality of electrically conductive tracks.
